(19) United States
(12) Patent Application Publication
(10) Pub. No.: US 2003/0102940 A1
(43) Pub. Date: Jun. 5, 2003

(54) MODIFIED SOLID GROUND ELECTRODE IN A CRYSTAL FILTER DEVICE

(76) Inventors: Richard Tzelin Wong, Bartlett, IL (US); Ealeana Kathryn Ostrem, Schaumburg, IL (US)

Correspondence Address: STEVEN WESEMAN, CTS CORPORATION, 171 COVINGTON DRIVE, BLOOMINGDALE, IL, 60108, US

(21) Appl. No.: 10/000,391

(22) Filed: Nov. 30, 2001

(51) Int. Cl. H03H 9/56

(52) U.S. Cl. 333/191; 333/192

(57) ABSTRACT

An electronic device includes a crystal filter device (500) that includes a crystal substrate having a top surface and a bottom surface that substantially opposes the top surface, a plurality of electrodes (502, 504, 506) disposed on the bottom surface. A first electrode (512) disposed on the top surface substantially opposes a first (502) of the plurality of electrodes on the bottom surface to thereby define a first resonator (530) of a plurality of resonators (530, 540, 550) across the crystal substrate. A second electrode (510) disposed on the top surface substantially opposes the remaining electrodes (504, 506) of the plurality of electrodes disposed on the bottom surface to thereby define the remaining resonators (540, 550), other than the first resonator (530), of the plurality of resonators across the crystal substrate. The first electrode (512) and the second electrode (510) disposed on the top surface are electrically coupled together.

### BACKGROUND OF THE INVENTION

1. Field of the Invention

This invention relates in general to crystal filter devices, and more particularly to an electrode connection configuration for a crystal filter device.

2. Description of the Related Art

Modern electronic devices, such as cellular phones, radios, paging devices, wireless communicators, satellite communication interfaces, high speed network interfaces, video communication interfaces, and high speed computing devices, to mention just a few examples, typically utilize frequency component devices in high frequency circuits to provide signals at the desired frequencies. Such frequency component devices include crystal filter devices that in a high frequency circuit typically provide an electronic signal within a predefined frequency range. The crystal frequency devices typically include filter circuits to tune the output electronic signal to best operate within the predefined frequency range. Due to the demanding frequency requirements of modern communication devices the crystal frequency devices usually include a number of filter poles to shape the frequency response of the output electronic signal from the crystal frequency devices. It is very common to utilize three or more poles for filtering the frequency response of the crystal frequency devices.

Additionally, there is a continuous trend to miniaturize electronic devices to maintain commercial viability for modern products as demanded by consumers. This trend to make electronic devices smaller construction directly impacts the size and manufacturability of the crystal frequency devices. These devices tend to be increasingly more difficult to produce within the smaller size constraints. One key concern is the manufacturability of the electrodes and conductors disposed on the outer surfaces of the crystal frequency devices. As the dimensions of the conductors decrease, the manufacturing tolerances between the conductors become much more important. Also, especially in piezoelectric crystal filter devices, additional filter poles commonly require additional electrical connections on the outer surfaces of a device, such as to connect to all of the individual resonators of a piezoelectric crystal filter. These additional conductors on the outer surface of an ever decreasing package size, with a smaller active area to accommodate the additional electrical connections, further aggravate the manufacturing tolerances between conductors. Therefore, the increasing number of filter poles for improved frequency shaping of the output signal while continuously decreasing the size of the crystal filter devices, creates a serious manufacturability issue especially for mass manufacturing systems.

Referring to FIG. 1, a first example of a prior art three-pole monolithic filter incorporating three resonators is shown. A piezoelectric plate 16 has an upper 18 and a lower surface 20 with three resonators 10, 12, 14 defined by opposing electrode pairs. An input electrical trace 22 is coupled to a top electrode 30 of a first resonator 10 and a first ground electrical trace 24 is coupled to a bottom electrode 32 of the first resonator 10. An output electrical trace 26 is coupled to a top electrode 40 of a last resonator 14 and a second ground electrical trace 28 is coupled to a bottom electrode 38 of the last resonator 14. A third ground electrical trace 42 is coupled to a top electrode 34 of a middle resonator 12 with a bottom electrode 36 of the middle resonator 12 coupled to the bottom electrodes 32, 38 of the first and last resonators 10, 14.

As can be seen, the third ground electrical trace 42 requires additional room on the piezoelectric plate 16 to run towards an edge of the plate. As is known in the art, vibrations under the active area (electrodes) of the filter resonators must not be dampened if at all possible. This can only be accomplished by mounting the plate or wirebonding to the electrodes at locations on the plate farthest away from the active area. This has necessitated the use of devices such as the third electrical trace 42 in prior art multi-pole filters. Disadvantageously, this filter and its electrical connections can only be realized by using a larger plate that requires a larger package or by shrinking the active area (electrodes) on the piezoelectric plate that impairs performance.

Referring to FIG. 2, a second example of a prior art device that includes a two-pole filter is shown. This device is similar to the description of the prior art device shown in FIG. 1, described above. However, this device, instead of having a middle resonator, has narrow shield electrodes 46 between the input and output electrodes 30, 40. In addition, this device has the input and output electrical traces 22, 26 on different sides of the piezoelectric plate and a fourth ground trace 44 coupled to a bottom shield electrode. This two-pole filter has the same disadvantage as the three-pole filter of FIG. 1, in that, the third (and fourth) ground electrical trace 42 (and 44) requires additional room on the piezoelectric plate 16.

FIG. 3 illustrates a third example of a prior art device that includes a three-pole filter. A piezoelectric blank 56 has major opposing upper 58 and lower surfaces 60 with at least three acoustically coupled resonators 50, 52, 54 defined by opposing electrode pairs disposed thereon. An input electrical connection 62 is coupled to a top electrode 70 of a first resonator 50 and a first ground electrical connection 64 is coupled to a bottom electrode 72 of the first resonator 50. An output electrical connection 68 is coupled to a bottom electrode 80 of a last resonator 54 and a second ground electrical connection 66 is coupled to a top electrode 78 of the last resonator 54. The top and bottom electrodes 74, 76 of each remaining resonator 52 are coupled to a similar potential (e.g., connected to each other and electrically floating or commonly coupled to the same potential such as ground).

A bottom electrode 76 of the middle resonator 52 is electrically coupled to the bottom electrode 72 of the first resonator 50 via a single first electrical trace 82. A top electrode 74 of the middle resonator 52 is electrically coupled to the top electrode 78 of the last resonator 54 via a single second electrical trace 84. In this example, the top and bottom electrodes 74, 76 of the middle resonator 52 are electrically coupled to ground via the first and second ground electrical connections 64, 66.

The top and bottom electrodes of all the resonators, in this example, have substantially similar horizontal and vertical dimensions, and the resonators are located colinearly along a horizontal direction of the piezoelectric blank. Also, as shown, the electrodes are connected by metallized traces to connection pads 86 located substantially on a periphery of the piezoelectric blank. Package connections to the crystal filter device, as shown in FIG. 3, include an input, an output, and at least one ground connection.

Note that the electrode configuration shown in FIG. 3 locates on one side of the device an input electrode 70 with a ground pair of electrodes 74, 78, while on the other side of the device is an output electrode 80 with a ground pair of electrodes 72, 76. The three electrodes on each side are of substantially similar dimensions. Therefore, the overall electrode surface on one side is divided into thirds, where ⅓ is associated with the input (or the output) electrode while the other two thirds is associated with a ground potential.

Referring to FIG. 4, a fourth example of a prior art device 400 that includes a three-pole filter is shown. This device 400 is similar to the description of the prior art device shown in FIG. 1, described above. However, the three electrodes on one side of the device 400 are integrated into one contiguous ground plane 410 that is electrically coupled to ground via first 412 and second 414 electrical traces. On the other side of the device 400, there are three electrodes 402, 404, 406. The first electrode is electrically coupled to an input, the third electrode 404 is electrically coupled to an output, and the second (middle) electrode is electrically coupled to ground. It is understood that the electrodes are connected by the respective electrical traces to connection pads (not shown) located substantially about a respective periphery of the device 400. These connection pads (not shown) typically may appear as an enlarged surface area generally in the shape of a letter “T”, such as illustrated in FIG. 1.

According to this fourth example, the single large ground plane 410 provides an opportunity for easier manufacturability for the electrode pattern on that particular side of the device 400. However, the overall frequency shaping capability of the three pole filter device is reduced due to the single contiguous ground plane 410.

Accordingly, there exists a need for overcoming the disadvantages of the prior art as discussed above, and in particular to improve the frequency shaping capability of the crystal filter devices while allowing manufacturability of additional electrodes on the surfaces of decreased size devices.

### SUMMARY OF THE INVENTION

A preferred embodiment of the present invention comprises a crystal filter device comprising a crystal substrate having a top surface and a bottom surface that substantially opposes the top surface; a plurality of electrodes disposed on the bottom surface, the plurality of electrodes defining a plurality of resonators across the crystal substrate; a first electrode disposed on the top surface to substantially oppose a first of the plurality of electrodes on the bottom surface to thereby define a first resonator of the plurality of resonators across the crystal substrate; and a second electrode disposed on the top surface to substantially oppose the remaining electrodes of the plurality of electrodes disposed on the bottom surface to thereby define the remaining resonators, other than the first resonator, of the plurality of resonators across the crystal substrate, and wherein the first electrode and the second electrode disposed on the top surface are electrically coupled together.

According to a preferred embodiment of the present invention, the crystal filter device comprises the first electrode disposed on the top surface and the second electrode disposed on the top surface in combination defining a total overall surface area defined for electrodes on the top surface, and wherein the surface area of the first electrode is defined as substantially the portion (one divided by the total number of the plurality of resonators) of the total overall surface area defined for electrodes on the top surface, and wherein the surface area of the second electrode is defined as substantially the portion [(the total number of the plurality of resonators minus 1) divided by the total number of the plurality of resonators] of the total overall surface area defined for electrodes on the top surface.

Preferably, the first electrode and the second electrode on the top surface are both substantially rectangular shape.

Preferably, the first electrode and the second electrode on the top surface are both substantially colinear.

According to a preferred embodiment of the present invention, a multi-pole monolithic crystal filter comprises a piezoelectric blank having an upper and lower surface; at least three resonators defined by substantially opposing top and bottom electrodes disposed on the upper and lower surfaces of the piezoelectric blank, the at least three resonators being acoustically coupled to each other; an input connection electrically coupled to a first bottom electrode of a first resonator of the at least three resonators, and an output connection electrically coupled to a second bottom electrode of a second resonator of the at least three resonators, and a ground connection electrically coupled to a third bottom electrode of a third resonator of the at least three resonators, the third resonator being located between the first resonator and the second resonator; the bottom electrode of each remaining resonator of the at least three resonators being electrically coupled to a ground connection; a first top electrode being in opposing orientation with the first bottom electrode to define the first resonator, the first top electrode being electrically coupled to a connection for a first potential; and a second top electrode being in opposing orientation with the remaining bottom electrodes of the remaining resonators of the at least three resonators, the second top electrode being electrically coupled to a connection for the first potential.

The crystal filter devices, according to preferred embodiments of the present invention, are advantageously used in electronic circuits for any of cellular phones, radios, paging devices, wireless communicators, satellite communication interfaces, high speed network interfaces, video communication interfaces, and high speed computing devices.

Other aspects, features, and advantages of the present invention will become apparent from the following detailed description and the accompanying drawings. It should be understood, however, that the detailed description and specific examples, while indicating preferred embodiments of the present invention, are given by way of illustration only and various modifications may naturally be performed without deviating from the present invention.

### BRIEF DESCRIPTION OF THE DRAWINGS

FIGS. 1, 2, and 3, are perspective views of exemplary prior art crystal filter devices.

FIGS. 4A and 4B are planar views of two opposing sides (Bottom Layer and Top Layer) of an exemplary three-pole prior art crystal filter device, illustrating shapes and arrangements of electrodes and electrical traces.

FIGS. 5A and 5B are planar views of two opposing sides (Bottom Layer and Top Layer) of a three-pole crystal filter device, illustrating shapes and arrangements of electrodes and electrical traces, in accordance with a preferred embodiment of the present invention.

FIGS. 6A and 6B are a second set of planar views of the crystal filter device illustrated in FIGS. 5A and 5B, more specifically illustrating the shapes and arrangements of the electrodes, in accordance with a preferred embodiment of the present invention. The broken lines in FIGS. 6A and 6B are for illustrative purposes only to show environment and form no part of the novel shapes and arrangements of the electrodes.

FIG. 7A and 7B are planar views of two opposing sides (Bottom Layer and Top Layer) of a four-pole crystal filter device, illustrating shapes and arrangements of electrodes and electrical traces, in accordance with a preferred embodiment of the present invention.

FIGS. 8A and 8B are a second set of planar views of the crystal filter device illustrated in FIGS. 7A and 7B, more specifically illustrating the shapes and arrangements of the electrodes, in accordance with a preferred embodiment of the present invention.

The broken lines in FIGS. 8A and 8B are for illustrative purposes only to show environment and form no part of the novel shapes and arrangements of the electrodes.

FIG. 9 is a graph illustrating a frequency response plot of a prior art crystal filter device such as shown in FIG. 1.

FIG. 10 is a graph illustrating a frequency response plot of a crystal filter device conforming to that shown in FIGS. 5A and 5B, in accordance with a preferred embodiment of the present invention.

FIG. 11 is a perspective view of a crystal filter device conforming to that illustrated in FIGS. 5A and 5B, according to a preferred embodiment of the present invention.

FIG. 12 is a graph illustrating a more detailed view about the pass band of the frequency response plot shown in FIG. 9.

FIG. 13 is a graph illustrating a more detailed view about the pass band of the frequency response plot shown in FIG. 10.

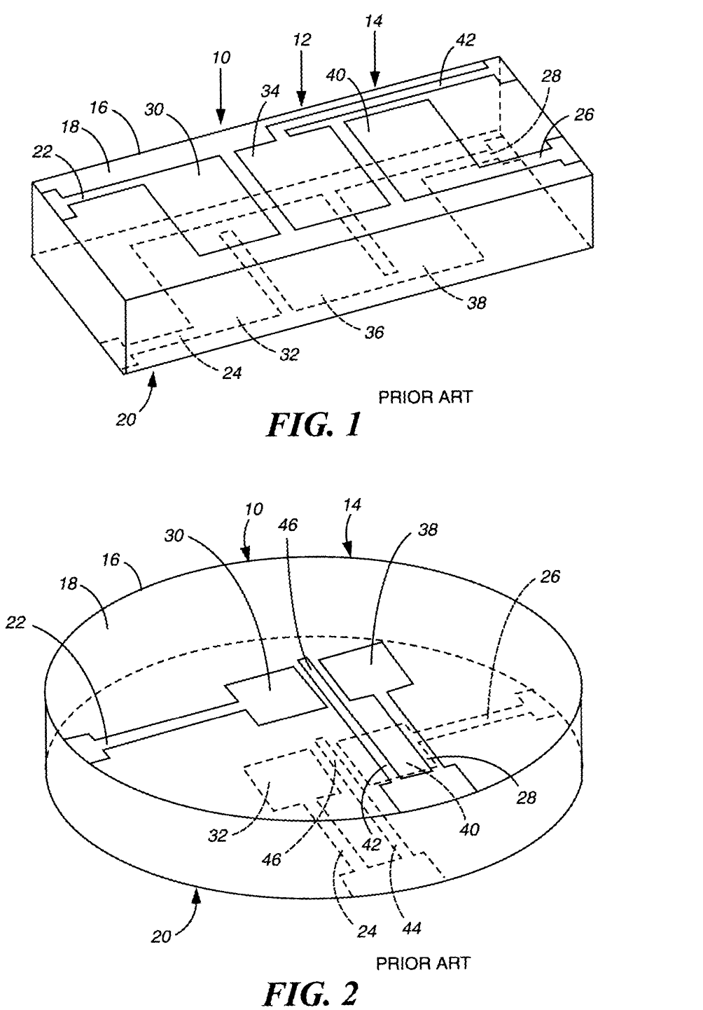

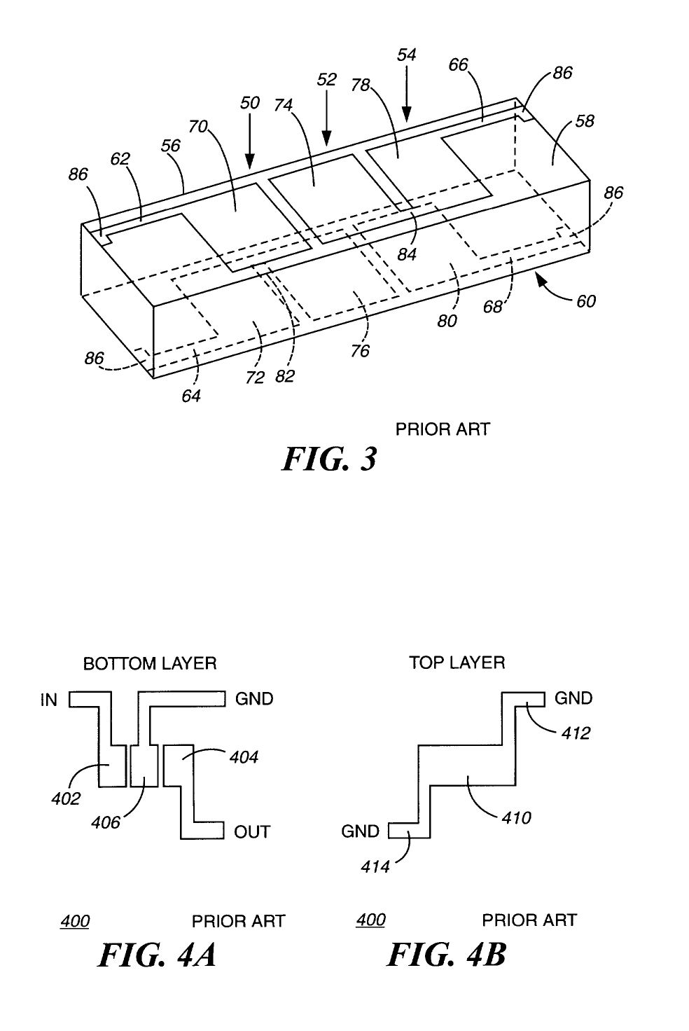

### DESCRIPTION OF THE PREFERRED EMBODIMENTS

It is important to note, that the embodiments discussed below are only examples of the many advantageous uses of the innovative teachings herein. In general, statements made in the specification of the present application do not necessarily limit any of the various claimed inventions. Moreover, some statements may apply to some inventive features but not to others. In general, unless otherwise indicated, singular elements may be in the plural and visa versa with no loss of generality.

A preferred embodiment of the present invention provides a multi-pole crystal filter device, for example a monolithic crystal filter of three poles or more, with an electrical connection configuration that enhances the overall frequency response of the crystal filter device while reducing package dimensions and maintaining manufacturing tolerances to enhance manufacturability in a mass manufacturing environment. The novel electrode shapes and configuration reduce the area required for the electrodes on the outer surface of a crystal filter device, while enhancing the frequency response of the multi-pole crystal filter device. Out-of-band spurious emissions are reduced while in-band frequency response is widened and enhanced to improve the electrical operation in a high frequency circuit application.

A preferred embodiment accomplishes the aforementioned advantages in a multi-pole monolithic crystal filter device. Preferably, the device includes a resonator for each filter pole. Advantageously, multi-pole filters can be provided on piezoelectric blanks.

By integrating certain electrode connections with neighboring electrode connections, as will be discussed in more detail below, a multi-pole crystal filter device can achieve enhanced frequency response and at the same time improve manufacturing tolerances for the electrodes. This is a significant improvement over the known prior art, as will be discussed in detail below.

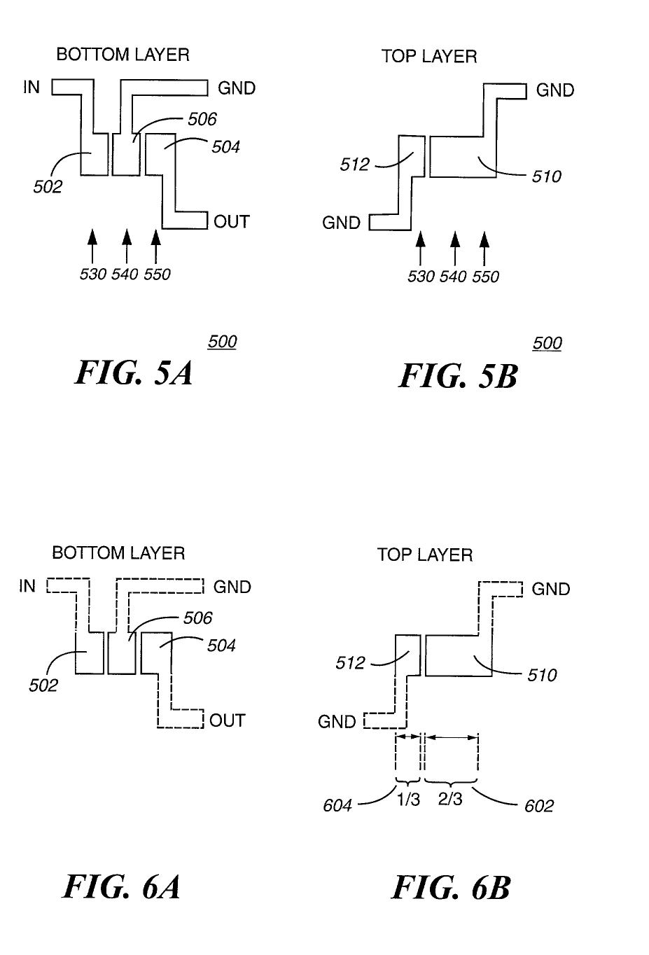

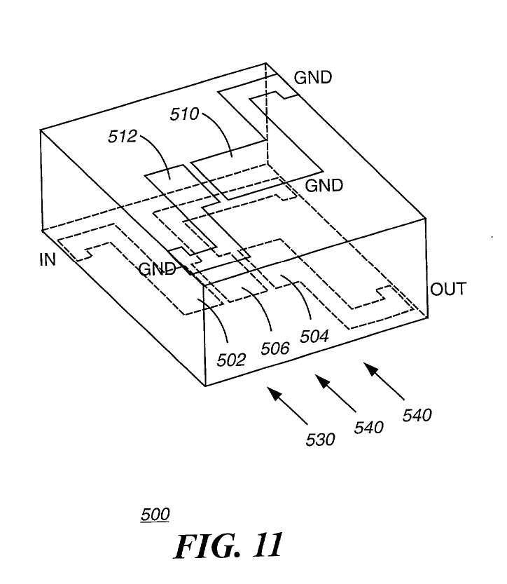

For the sake of simplicity in the discussions below with respect to FIGS. 5A, 5B, 6A, 6B, 7A, 7B, 8A,and 8B, it is understood that electrodes are electrically coupled by respective electrical traces to connection pads (not shown) located substantially about a respective periphery of the respective device. These connection pads (not shown) preferably appear as an enlarged surface area generally in the shape of a letter “L”. See, for example, the generally “L” shaped connection pads about the IN, OUT, and GND, electrical connections of the device illustrated in FIG. 11. Additionally, it should be clear that the layers shown in the FIGS. 5A, 5B, 6A, 6B, 7A, 7B, 8A and 8B, are to be viewed all from the same direction. That is, for example, the Bottom Layer and Top Layer shown in FIGS. 5A and 5B, respectively, may be superimporsed on each other to view the relative positions of the electrodes and electrical traces between FIGS. 5A and 5B in the particular illustrated exemplary embodiment. See for example the device illustrated in FIG. 11 corresponding to that shown in FIGS. 5A and 5B.

Referring to FIGS. 5A, 5B, 6A, and 6B, an exemplary three-pole crystal filter device 500 is illustrated, according to a preferred embodiment of the present invention. See also FIG. 11 for a corresponding perspective view of the new and novel device 500. Although the present examples will be discussed with reference to a monolithic crystal multi-pole filter device, such as including a piezoelectric crystal with a plurality of resonators, e.g., one resonator per filter pole, alternative preferred embodiments of the present invention can generally comprise different types of crystal filter devices as will be obvious to those of ordinary skill in the art in view of the present discussion.

The present discussions generally assume the teachings of a monolithic multi-pole crystal filter device as described in U.S. Pat. No. 6,020,797, issued Feb. 1, 2000 to Adamski et al., and assigned to the assignee of the present invention, and which is hereby fully incorporated herein by reference.

The present example, being discussed with reference to FIGS. 5A, 5B, 6A, and 6B, includes a monolithic crystal filter device 500, such as including a quartz crystal blank (not shown), having major opposing upper and lower surfaces with at least three acoustically coupled resonators 530, 540 and 550 defined by opposing electrode pairs disposed thereon. A crystal blank slab preferably is generally square in shape in the surfaces for electrodes and traces, as will be discussed below. A first resonator 530 is defined by an input signal electrode 502 and a ground electrode 512 on the opposing major surface of the crystal filter device 500. Note that the input signal electrode 502 is electrically coupled to an input signal contact. The second resonator 540 is defined by electrode 506 electrically coupled to ground and an opposing portion of the ground electrode 510 disposed on the opposing major surface of the crystal filter device 500. The third resonator 550 is defined by output signal electrode 504 and an opposing portion of the ground electrode 510 disposed on the opposing major surface of the crystal filter device 500. Note that the output signal electrode 504 is electrically coupled to an output signal contact.

As shown in FIGS. 6A and 6B, the electrode shapes and arrangements, according to a preferred embodiment of the present invention, are defined with the two main ground electrodes 510, 512 on the Top Layer of the device 500 being suitably sized, shaped, and arranged, such that in a three electrode pair embodiment, e.g., in a three-pole filter crystal device, the smaller ground electrode 512 is approximately one-third (⅓) of the surface 604, i.e., generally one (1) divided by the total number of electrode pairs, of the total overall surface area defined for the ground electrodes 510, 512 on the Top Layer of the device 500. Further, the larger ground electrode 510 is approximately two-thirds (⅔) of the surface 602, i.e., generally (the number of electrode pairs minus one) divided by the total number of electrode pairs, of the total overall surface area defined for the ground electrodes 510, 512.

Note that for a substantially rectangular shaped set of electrodes with substantially similar height dimensions, the width dimension of each of the electrodes directly impacts the amount of surface area defined for the particular electrode. In the present example, the smaller ground electrode 512 is approximately ⅓ of the total width dimension 604, while the larger ground electrode 510 is approximately ⅔ of the total width dimension 602. This ratio of width dimensions between the two electrodes is directly corresponding to the ratio of the overall surface areas defined for the two electrodes. Further, it should be obvious to those of ordinary skill in the art that other electrode shapes can likewise be portioned to correspond to a defined ration between the overall surface areas defined for a particular set of electrodes.

The spacing (gap distances) between the smaller ground electrode 512 and the larger ground electrode 510 may be increased to allow larger manufacturing tolerances in the location of the two electrodes 510, 512 on the surface of the device 500. For example, while a conventional gap between electrodes may require between 1 and 2.5 mils (thousands of an inch), the gap distance between the smaller ground electrode 512 and the larger ground electrode 510 may, advantageously, be increased to between 2.5 and 3.5 mils, in accordance with a preferred embodiment of the present invention. A typical electrode 506 preferably has a size of about 19 by 29 mils. Therefore, the larger gap distance, relative to the size of electrodes, provided by the preferred embodiments of the present invention enhances manufacturability. At the same time, the preferred electrode size portioning of the ground electrodes 510, 512 as discussed above, by approximately ⅓ for the smaller ground electrode 512 and approximately ⅔ for the larger ground electrode 510, provides an enhanced frequency response for the device 500. The device 500 in an electronic circuit provides a wider frequency pass band for a desired electronic signal while significantly attenuating undesired out-of-band spurious emissions produced by the device 500 in the electronic circuit. This is a significant advantage of the present invention not found in prior art devices.

Additionally, in the present example, the three sets of opposing top and bottom electrodes define acoustically coupled resonators on a piezoelectric blank. Preferably, vapor deposition is typically employed to dispose the resonators on the blank. The resonators include a first resonator 530 corresponding to an input side of the filter 500, a third resonator 550 corresponding to an output side of the filter 500, and the second (middle) resonator 540. Each electrode is preferably formed of an electrically conductive material, typically aluminum or chrome/gold, which is plated on the upper and lower surfaces of the piezoelectric blank to a predetermined thickness. Electrical coupling between electrodes and other circuit elements or connections can be accomplished by depositing a thin strip of electrically conductive material (electrical trace) which is large enough to provide a low resistance connection to the electrodes.

Also, in a preferred embodiment the disposing step includes disposing the top and bottom electrodes of all the resonators to have substantially similar horizontal and vertical dimensions, and disposing the resonators colinearly along a horizontal direction of the piezoelectric blank.

It should be recognized that the present invention can easily be expanded into alternative embodiments having four or more filter poles, in accordance with the present description, and as will be discussed in more detail below.

Preferably, the top and bottom electrodes of all resonators in an embodiment will have substantially similar horizontal and vertical dimensions, and the resonators preferably are located colinearly along a horizontal direction of a piezoelectric blank.

According to a preferred embodiment of the present invention, a piezoelectric plate is made of quartz crystal. More preferably, the piezoelectric plate is of an AT-cut crystallographic orientation of quartz with the pairs of electrodes aligned along the X or Z crystallographic axis of the quartz. However, it should be recognized that all other piezoelectric materials and orientations commonly known in the art can be used equally well without limitation.

A preferred embodiment of the present invention is realized on a piezoelectric blank having almost square upper and lower surfaces. Alternatively, the piezoelectric blank is rectangular with its long dimension along a horizontal direction.

In accordance with a preferred embodiment of the present invention, the resonators are positioned colinearly, defined as the center of each resonator lying substantially along a line substantially perpendicular to a center line bisecting the piezoelectric blank, and all resonators resonate at about the same frequency. However, it is not a requirement of the present invention that resonators be located colinearly on a piezoelectric blank or that resonators be of the same area or dimensions.

A typical operation of the preferred device 500, according to a preferred embodiment of the present invention, will now be discussed with reference to FIGS. 5A, 5B, and 11. An input signal is electrically coupled to the input signal electrode 502. Due to the physical property of piezoelectric material, the electrical energy is converted into mechanical energy. This mechanical energy comprises acoustical waves. Each acoustical wave propagates outward from the input resonator 530 and starts to excite the middle ground electrode 506 on the Bottom Layer. The middle ground electrode 506 starts to resonate, and acoustical waves propagate therefrom and start to excite the output signal electrode 504. Also, due to the physical properties of piezoelectric material, the mechanical energy (related to the acoustical waves) at the third resonator 550 is converted into electrical energy at the output signal electrode 504, which is then electrically coupled to an output circuit via an output signal trace and an output connection pad to OUT, such as shown in FIG. 11.

Due to the energy loss as the acoustical waves traverse over the piezoelectric material, the spacing of the electrodes plays a major role in the initial width of the frequency passband, i.e., before making frequency adjustments to the device 500. The closer the electrodes are located relative to each other on the Bottom Layer, without making direct electrical contact with each other, the wider the initial frequency passband will be possible before any frequency adjustment is made to the device 500. However, manufacturing techniques and the ability to make frequency adjustments to the device 500 will determine how close the electrodes may be located. Frequency adjustment is a procedure of depositing (or removing) mass to/from the electrodes to adjust the resonant frequencies of the electrodes for a particular desired overall frequency response of the device 500.

Note that a large single ground electrode 410, such as discussed with reference to prior art FIGS. 4A and 4B, may allow a wider initial frequency passband (before frequency adjustment). However, due to the large single electrode 410, other unwanted spurious modes get excited and transferred to the output. The unwanted spurious modes get less attenuation, which can cause significant problems for particular applications using the prior art device 400.

Advantageously, the preferred embodiments of the present invention, such as illustrated in FIG. 11, utilize less than an entire single ground electrode on the Top Layer, resulting in sufficiently wide initial frequency passband (before making frequency adjustment), and with less energy to excite unwanted spurious modes at the output signal electrode 504. For example, since the larger ground electrode 510, in FIG. 5B, is sized at approximately ⅔ of the entire electrode area, there will be a sufficiently wide initial frequency passband (due to the substantially larger ground electrode 510) while less energy is transferred to the output signal electrode than in the prior art device illustrated in FIGS. 4A and 4B. Less energy will therefore be available to excite the unwanted spurious modes at the output signal electrode 504. This feature of the preferred embodiment of the present invention provides significantly better spurious attenuation than prior art devices, such as those shown in FIGS. 4A and 4B.

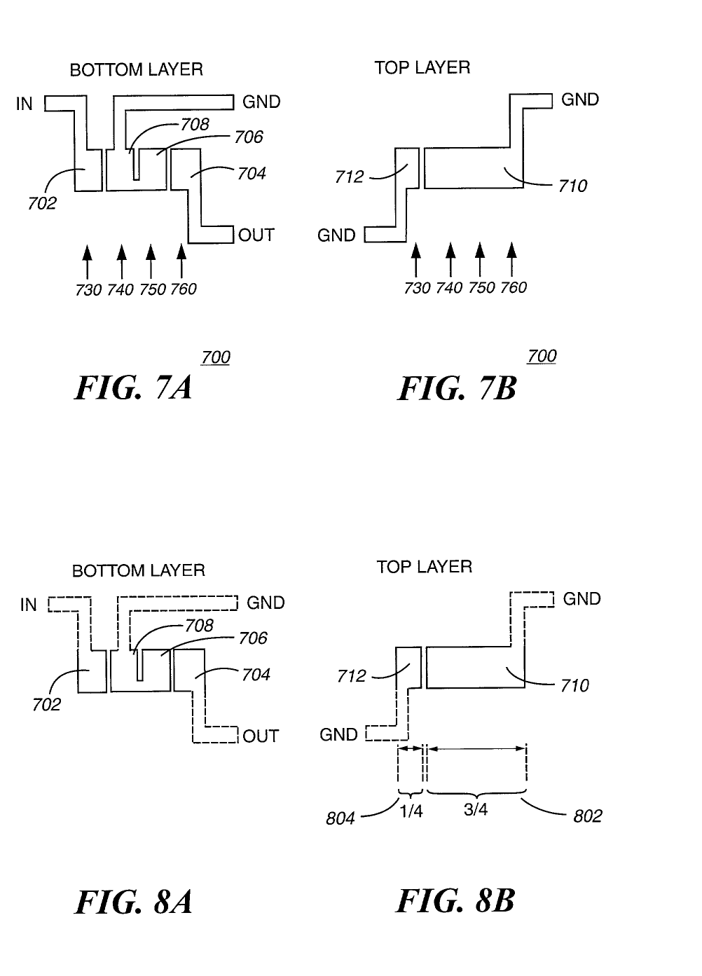

Referring to FIGS. 7A, 7B, 8A and 8B, an exemplary four-pole crystal filter device 700 is illustrated, according to a preferred embodiment of the present invention. The discussion of this device 700 is analogous to the previous discussion with respect to the three-pole device 500, with reference to FIGS. 5A, 5B, 6A and 6B. However, instead of three resonators as discussed above for the three-pole crystal filter device 500, the present exemplary four-pole crystal filter device 700 includes four resonators. Although the present example is discussed with reference to a monolithic crystal multi-pole filter device, such as including a piezoelectric crystal with a plurality of resonators, e.g., one resonator per filter pole, alternative preferred embodiments of the present invention can generally comprise different types of crystal filter devices as will be obvious to those of ordinary skill in the art in view of the present discussion.

The present example, being discussed with reference to FIGS. 7A, 7B, 8A and 8B, includes a monolithic crystal filter device 700, such as including a quartz crystal blank (not shown), having major opposing upper and lower surfaces with at least four acoustically coupled resonators 730, 740, 750 and 760, defined by opposing electrode pairs disposed thereon. A first resonator 730 is defined by a first (input) electrode 702 and opposing a ground electrode 712 on the opposing major surface of the crystal filter device 700. Note that the input signal electrode 702 is electrically coupled to an input signal contact. The second resonator 740 is defined by a second electrode 708 electrically coupled to ground and opposing a portion of the ground electrode 710 disposed on the opposing major surface of the crystal filter device 700. The third resonator 750 is defined by third electrode 706 electrically coupled to the second electrode 708 (that is electrically coupled to ground) and the third electrode 706 opposing a portion of the ground electrode 710 disposed on the opposing major surface of the crystal filter device 700. The fourth resonator 760 is defined by fourth (output) electrode 704 and opposing a portion of the ground electrode 710 disposed on the opposing major surface of the crystal filter device 700. Note that the output signal electrode 704 is electrically coupled to an output signal contact. Four distinct electrode resonators are defined in the Bottom Layer according to this example for defining transmission zeroes of the four-pole filter design. Each of the four electrode resonators will be tuned to a different frequency in this example. Therefore, there are gaps, as shown, between each of the four electrodes 702, 704, 706 and 708 on the Bottom Layer. In particular, a preferred embodiment includes a gap between the two middle electrodes 706, 708 even though these are both electrically coupled to the same ground potential. An electrical trace is preferably used to electrically couple the two middle electrodes 706, 708, as shown in FIGS. 7A, 7B, 8A, and 8B.

As shown in FIGS. 8A and 8B, the electrode shapes and arrangements, according to a preferred embodiment of the present invention, are defined with the two main ground electrodes 710, 712 on the Top Layer of the device 700 being suitably sized, shaped, and arranged, such that in a four electrode pair embodiment, e.g., in a four-pole filter crystal device, the smaller ground electrode 712 is approximately one-quarter (¼) of the surface 804, i.e., generally one (1) divided by the total number of electrode pairs, of the total overall surface area defined for the ground electrodes 710, 712 on the Top Layer of the device 700. Further, the larger ground electrode 710 is approximately three-quarters (¾) of the surface 802, i.e., generally (the number of electrode pairs minus 1) divided by the total number of electrode pairs, of the total overall surface area defined for the ground electrodes 710, 712.

Note that for a substantially rectangular shaped set of electrodes with substantially similar height dimensions, the width dimension of each of the electrodes directly impacts the amount of surface area defined for the particular electrode. In the present example, the smaller ground electrode 712 is approximately ¼ of the total width dimension 804, while the larger ground electrode 710 is approximately ¾ of the total width dimension 802. This ratio of width dimensions between the two electrodes is directly corresponding to the ratio of the overall surface area defined for the two electrodes.

It should be obvious to those of ordinary skill in the art, in view of the present discussion, that other electrode shapes and sizes can likewise be portioned to correspond to a defined ratio between the overall surface areas defined for a particular set of electrodes. For example, a 2/4 portioning of a total width dimension between two ground electrodes (not shown) may be used in a particular application to achieve the desired results of enhanced frequency response for a particular device. That is, four electrodes 702, 704, 706 and 708 of the Bottom Layer opposing two ground electrodes (not shown) of the Top Layer, wherein electrodes 707 and 708 of the Bottom Layer oppose one of the two ground electrodes of the Top Layer, and electrodes 704 and 706 of the Bottom Layer oppose the other of the two ground electrodes of the Top Layer.

Advantageously, the spacing (gap distances) between the smaller ground electrode 712 and the larger ground electrode 710 can be increased to allow larger manufacturing tolerances in the location of the two electrodes 710, 712 on the surface of the device 700. For example, while a conventional gap between electrodes may require between 1 and 2.5 mils (thousands of an inch), the gap distance between the smaller ground electrode 712 and the larger ground electrode 710 can, advantageously, be increased to between 2.5 and 3.5 mils, in accordance with a preferred embodiment of the present invention. This larger gap distance enhances manufacturability. At the same time, the preferred electrode size portioning of the ground electrodes 710, 712 as discussed above, by approximately ¼ for the smaller ground electrode 712 and approximately ¾ for the larger ground electrode 710, provides an enhanced frequency response for the device 700. The device 700 in an electronic circuit provides a wider frequency pass band for a desired electronic signal while significantly attenuating undesired out-of-band spurious emissions produced by the device 700 in the electronic circuit. This is a significant advantage of the present invention not found in prior art devices.

It should be recognized that the present invention can easily be expanded into alternative embodiments having five or more filter poles, in accordance with the above exemplary descriptions.

The novel electrode shapes and configuration, as has been discussed above, reduce the area required for the electrodes on the outer surface of a crystal filter device. Additionally, the preferred embodiments of the present invention exhibit enhanced frequency response for the respective multi-pole crystal filter device. Out-of-band spurious emissions are reduced while in-band frequency response is widened and enhanced to improve the electrical operation in a high frequency circuit application.

FIG. 11 is a perspective view of a crystal filter device 500 conforming to that illustrated in FIGS. 5A and 5B, according to a preferred embodiment of the present invention. The crystal filter device 500 shown in FIG. 11 comprises a crystal blank. The crystal blank has a rectangular top surface and a rectangular bottom surface that are almost square, preferably having approximate dimensions of 900 mils×800 mils. The crystal blank has a substantially uniform height, preferably approximately 120 mils.

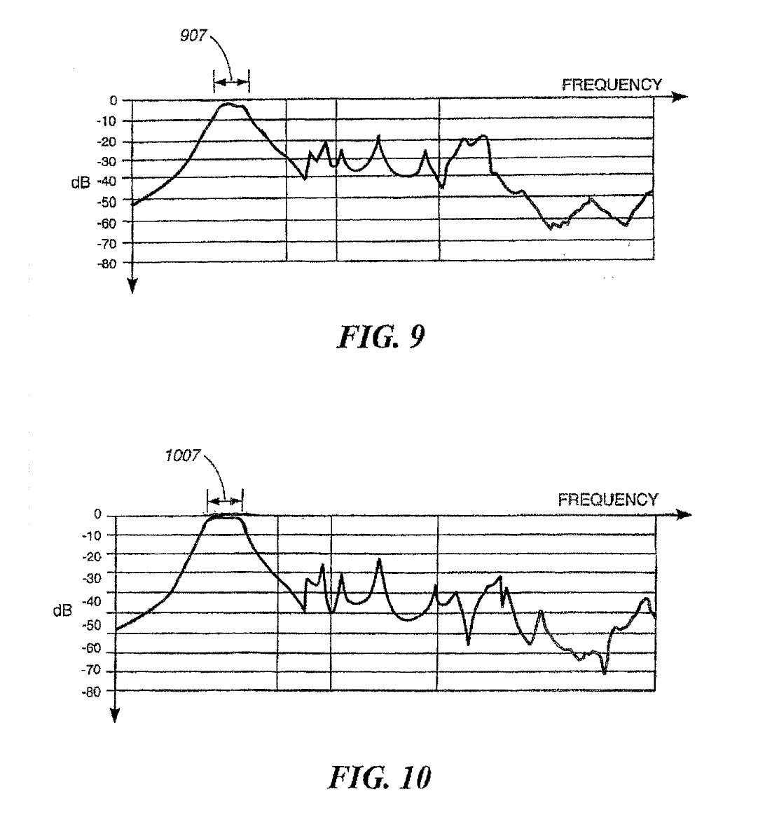

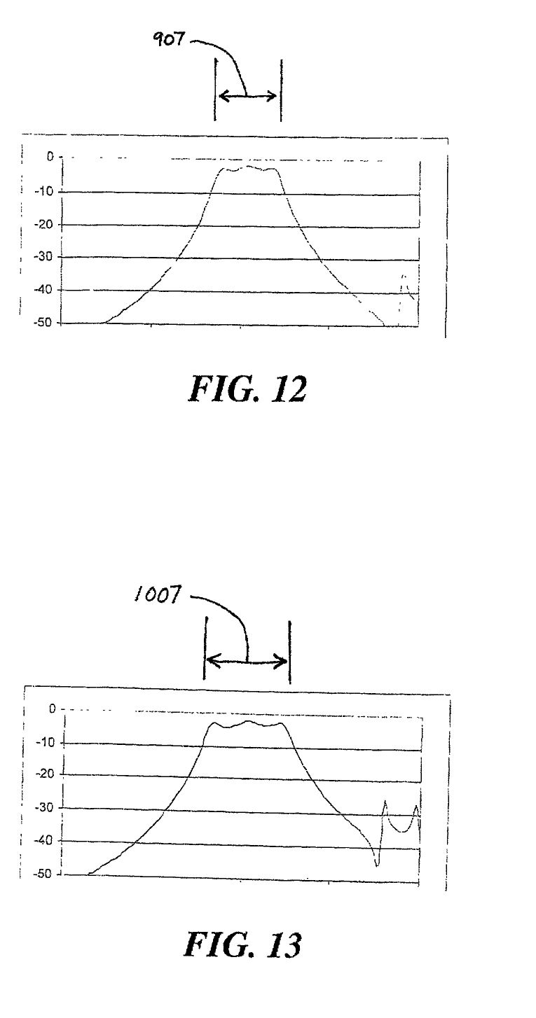

For example, the frequency response plots in FIGS. 9 and 10, and in a more detailed view illustrating the pass bands in FIGS. 12 and 13, respectively, show several enhancements in the frequency response of a preferred embodiment as shown in planar views in FIGS. 5A and 5B, and in perspective view in FIG. 11, over a prior art device such as shown in FIG. 1. First, the pass band 1007 of the crystal filter device 500 in a tuned circuit measured significantly wider than the pass band 907 of a prior art device (shown in FIG. 1) likewise measured in a tuned circuit. Additionally, as shown in FIGS. 9 and 10, the measured spurious emissions of the crystal filter device 500, respectively are, advantageously, generally attenuated from the measured spurious emissions of the prior art device (shown in FIG. 1). Note the measured spurious emissions of the crystal filter device 500, as shown in FIG. 10, are generally below 30 dB, while the measured spurious emissions of the prior art device (see FIG. 1), as shown in FIG. 9, are generally below only 20 dB. Therefore, there is a marked improvement in the spurious signal attenuation of the crystal filter device 500 over the prior art device of FIG. 1.

While there has been illustrated and described what are presently considered to be the preferred embodiments of the present invention, it will be understood by those of ordinary skill in the art that various other modifications may be made, and equivalents may be substituted, without departing from the true scope of the present invention.

Additionally, many modifications may be made to adapt a particular situation to the teachings of the present invention without departing from the central inventive concept described herein. Furthermore, an embodiment of the present invention may not include all of the features described above. Therefore, it is intended that the present invention not be limited to the particular embodiments disclosed, but that the invention include all embodiments falling within the scope of the appended claims.

What is claimed is:

1. A crystal filter device comprising:
a crystal substrate having a top surface and a bottom surface that substantially opposes the top surface;
a plurality of electrodes disposed on the bottom surface;
a first electrode disposed on the top surface to substantially oppose a first of the plurality of electrodes on the bottom surface to thereby define a first resonator of a plurality of resonators across the crystal substrate; and
a second electrode disposed on the top surface to substantially oppose the remaining electrodes of the plurality of electrodes disposed on the bottom surface to thereby define the remaining resonators, other than the first resonator, of the plurality of resonators across the crystal substrate, and wherein the first electrode and the second electrode disposed on the top surface are electrically coupled together.

2. The crystal filter device of claim 1, wherein the first electrode and the second electrode disposed on the top surface are each electrically coupled to an electrical contact for ground.

3. The crystal filter device of claim 1, wherein the first electrode of the plurality of electrodes on the bottom surface is electrically coupled to one of an input signal contact and an output signal contact for the crystal filter device, and wherein a second electrode of the plurality of electrodes on the bottom surface is electrically coupled to the other one of the input signal contact and the output signal contact for the crystal filter device.

4. The crystal filter device of claim 3, wherein the remaining electrodes, other than the first electrode and the second electrode, of the plurality of electrodes on the bottom surface are commonly electrically coupled.

5. The crystal filter device of claim 4, wherein the remaining electrodes of the plurality of electrodes on the bottom surface are commonly electrically coupled to an electrical contact for ground.

6. The crystal filter device of claim 1, wherein the plurality of resonators a cross the crystal substrate comprises at least three resonators.

7. The crystal filter device of claim 1, wherein the first electrode disposed on the top surface and the second electrode disposed on the top surface in combination define a total overall surface area defined for electrodes on the top surface, and wherein
the surface area of the first electrode is defined as substantially the portion (one divided by the total number of the plurality of resonators) of the total overall surface area defined for electrodes on the top surface, and wherein
the surface area of the second electrode is defined as substantially the portion [(the total number of the plurality of resonators minus 1) divided by the total number of the plurality of resonators] of the total overall surface area defined for electrodes on the top surface.

8. The crystal filter device of claim 1, wherein the total number of the plurality of resonators is three, and wherein the surface area of the first electrode substantially comprises ⅓ of a total overall surface area defined for electrodes on the top surface, and wherein the surface area of the second electrode substantially comprises ⅔ of the total overall surface area defined for electrodes on the top surface.

9. The crystal filter device of claim 1, wherein the first electrode and the second electrode on the top surface are both substantially rectangular shape.

10. The crystal filter device of claim 9, wherein the first electrode and the second electrode on the top surface are both substantially colinear.

11. The crystal filter device of claim 10, wherein the first electrode and the second electrode on the top surface both have substantially the same height dimension, and wherein
the width dimension of the first electrode is defined as substantially (one divided by the total number of the plurality of resonators) of a total width dimension defined for the first electrode and the second electrode on the top surface, and wherein
the width dimension of the second electrode is defined as substantially [(the total number of the plurality of resonators minus 1) divided by the total number of the plurality of resonators] of the total width dimension defined for the first electrode and the second electrode on the top surface.

12. The crystal filter device of claim 10, wherein the first electrode and the second electrode on the top surface both have substantially the same height dimension, and wherein the total number of the plurality of resonators is three, and wherein
the width dimension of the first electrode is defined as ⅓ of a total width dimension defined for the first electrode and the second electrode on the top surface, and wherein
the width dimension of the second electrode is defined as ⅔ of a total width dimension defined for the first electrode and the second electrode on the top surface.

13. A multi-pole monolithic crystal filter, comprising:
a piezoelectric blank having an upper and lower surface;
at least three resonators defined by substantially opposing top and bottom electrodes disposed on the upper and lower surfaces of the piezoelectric blank, the at least three resonators being acoustically coupled to each other;
an input connection electrically coupled to a first bottom electrode of a first resonator of the at least three resonators, and an output connection electrically coupled to a second bottom electrode of a second resonator of the at least three resonators, and a ground connection electrically coupled to a third bottom electrode of a third resonator of the at least three resonators, the third resonator being located between the first resonator and the second resonator;
a first top electrode being in opposing orientation with the first bottom electrode to define the first resonator, the first top electrode being electrically coupled to a connection for a first potential; and
a second top electrode being in opposing orientation with the remaining bottom electrodes of the remaining resonators of the at least three resonators, the second top electrode being electrically coupled to a connection for the first potential.

14. The multi-pole monolithic crystal filter of claim 13, wherein the first potential is ground.

15. The multi-pole monolithic crystal filter of claim 13, wherein the piezoelectric blank comprises an AT-cut crystallographic orientation of quartz.

16. The multi-pole monolithic crystal filter of claim 13, wherein the piezoelectric blank comprises rectangular shape.

17. The multi-pole monolithic crystal filter of claim 16, wherein the first top electrode an the second top electrode are both substantially rectangular shape.

18. The multi-pole monolithic crystal filter of claim 17, wherein the first top electrode and the second top electrode both have substantially the same height dimension.

19. The multi-pole monolithic crystal filter of claim 13, wherein the bottom electrode of each remaining resonator of the at least three resonators is electrically coupled to a ground connection;

20. An electronic device comprising:
an electronic circuit; and
at least one crystal filter device electrically coupled to the electronic circuit, and wherein each of the at least one crystal filter device comprising:
a crystal substrate having a top surface and a bottom surface that substantially opposes the top surface;
a plurality of electrodes disposed on the bottom surface;
a first electrode disposed on the top surface to substantially oppose a first of the plurality of electrodes on the bottom surface to thereby define a first resonator of a plurality of resonators across the crystal substrate; and
a second electrode disposed on the top surface to substantially oppose the remaining electrodes of the plurality of electrodes disposed on the bottom surface to thereby define the remaining resonators, other than the first resonator, of the plurality of resonators across the crystal substrate, and wherein the first electrode and the second electrode disposed on the top surface are electrically coupled together.
